(19) United States
(12) Patent Application Publication
(10) Pub. No.: US 2015/0179597 A1
(43) Pub. Date: Jun. 25, 2015

(54) SEMICONDUCTOR PACKAGE AND FABRICATION METHOD THEREOF

(71) Applicant: Siliconware Precision Industries Co., Ltd, Taichung (TW)

(72) Inventors: Pai-Yuan Li, Taichung (TW); Chun-Tang Lin, Taichung (TW)

(73) Assignee: SILICONWARE PRECISION INDUSTRIES CO., LTD, Taichung (TW)

(21) Appl. No.: 14/183,872

(22) Filed: Feb. 19, 2014

(30) Foreign Application Priority Data
Dec. 19, 2013 (TW) 102147135

(51) Int. Cl. H01L 23/00; H01L 23/29

(52) U.S. Cl. CPC H01L 24/17; H01L 24/81; H01L 23/29

(57) ABSTRACT

A semiconductor package is provided, which includes: a first electronic element; a plurality of conductive elements formed on the first electronic element; a second electronic element having a plurality of conductive bumps and disposed on the first electronic element through the conductive bumps, wherein the conductive bumps are correspondingly electrically connected to the conductive elements; and an underfill formed between the second electronic element and the first electronic element for encapsulating the conductive bumps and the conductive elements, wherein the underfill contains a plurality of conductive particles having a particle size between 0.1 and 1 um, a plurality of insulating particles having a particle size between 1 and 10 um and a polymer. The invention overcomes the conventional drawback of poor electrical connection between the second electronic element and the first electronic element through the conductive particles so as to enhance the electrical performance of the semiconductor package.

### BACKGROUND OF THE INVENTION

1. Field of the Invention

The present invention relates to semiconductor packages and fabrication methods thereof, and more particularly, to a semiconductor package and a fabrication method thereof for improving electrical performance.

2. Description of Related Art

Along with the rapid development of electronic industries, many high-end electronic products are developed toward the trend of high integration. Accordingly, various chip packaging technologies are developed. Therein, flip-chip bonding technologies facilitate to reduce chip packaging sizes and shorten signal transmission paths and therefore are widely used for chip packaging such as chip scale packaging (CSP).

In particular, to perform flip-chip bonding, a plurality of bonding pads arranged in an array are formed on a surface of an electronic element and a plurality of conductive bumps are formed on the bonding pads. Then, the conductive bumps of the electronic element are correspondingly bonded to solder contacts of a carrier through a reflow process, thereby electrically and mechanically connecting the electronic element to the carrier.

There are various types of chip scale packaging using flip-chip bonding. One type of chip scale packaging is wafer level chip scale packaging (WLCSP), which is directly performed on a wafer level. The wafer level chip scale packaging is characterized in that a redistribution layer (RDL) is formed on a surface of a chip to redistribute peripheral bonding pads of an electronic element to an area array of bonding pads evenly deployed on the surface of the electronic element, thereby increasing the pitch between the bonding pads so as to correspond to a printed circuit board having a small I/O count and a large pitch between contacts.

Further, a solder material can be formed on the bonding pads manually or automatically for electrically connecting the bonding pads to the contacts of the printed circuit board.

However, when the conductive bumps or solder material are melted during a reflow process, adjacent conductive bumps or solder material may come into contact with one another, thus reducing the product reliability. Therefore, a predetermined pitch must be kept between the bonding pads or the amount of the solder material must be reduced to prevent solder bridging from occurring between adjacent conductive bumps after a reflow process.

Further, thermal stresses may be generated due to a CTE (Coefficient of Thermal Expansion) mismatch between the electronic element and the carrier, and the conductive bumps may crack laterally under the effect of the thermal stresses. To overcome the drawback, an underfill is filled between the electronic element and the carrier to encapsulate the conductive bumps and the solder material.

FIG. 1 shows a conventional semiconductor package 1. Referring to FIG. 1, the semiconductor package 1 has: a carrier 10; an electronic element 11 having a plurality of conductive bumps 110; a solder material 12 formed between the conductive bumps 110 of the electronic element 11 and the carrier 10 for electrically and mechanically connecting the conductive bumps 110 to the carrier 10; and an underfill 13 formed between the electronic element 11 and the carrier 10 for encapsulating the conductive bumps 110 and the solder material 12. However, when the amount of the solder material is reduced to prevent solder bridging from occurring between adjacent conductive bumps, it may cause poor or no electrical or mechanical connection between the solder material 12′ and the conductive bumps 110 and even cause a non-wetting problem.

FIG. 1′ shows a flip-chip bonding technique using a pressed anisotropic conductive film (ACF). Referring to FIG. 1′, the anisotropic conductive film contains composite particles 9 that are formed by encapsulating conductive balls 92 with an insulating film 91. In flip-chip bonding, the anisotropic conductive film is pressed to cause the composite particle 9 to break. As such, the conductive balls 92 are exposed for electrical conduction. However, the pressed anisotropic conductive film has high resistance and needs to be cured at high pressure, and the composite particles are expensive. Further, an unsuitable size of the conductive balls 92 may cause bridging and reduce the product reliability. These drawbacks prevent the pressed anisotropic conductive film from being widely applied in electronic industries.

Therefore, there is a need to provide a semiconductor package and a fabrication method thereof so as to overcome the above-described drawbacks.

### SUMMARY OF THE INVENTION

In view of the above-described drawbacks, the present invention provides a semiconductor package, which comprises: a first electronic element; a plurality of conductive elements formed on the first electronic element; a second electronic element having a plurality of conductive bumps and disposed on the first electronic element through the conductive bumps, wherein the conductive bumps are correspondingly electrically connected to the conductive elements; and an underfill formed between the second electronic element and the first electronic element for encapsulating the conductive bumps and the conductive elements, wherein the underfill comprises: a plurality of conductive particles having a particle size between 0.1 and 1 um; a plurality of insulating particles having a particle size between 1 and 10 um; and a polymer.

In an embodiment, if a portion of the conductive bumps are not electrically connected to the corresponding conductive elements, in the underfill filled between the portion of the conductive bumps and the corresponding conductive elements, the content of the conductive particles is greater than the content of the insulating particles.

The present invention further provides a method for fabricating a semiconductor package, which comprises the steps of: providing a first electronic element having a plurality of conductive elements thereon and disposing a second electronic element on the conductive elements of the first electronic element through a plurality of conductive bumps; and filling an underfill between the second electronic element and the first electronic element for encapsulating the conductive bumps and the conductive elements, wherein the underfill comprises: a plurality of conductive particles having a particle size between 0.1 and 1 um; a plurality of insulating particles having a particle size between 1 and 10 um; and a polymer.

In an embodiment, if there is a gap between a portion of the conductive bumps and the corresponding conductive elements, the underfill is further filled between the portion of the conductive bumps and the corresponding conductive elements. In the underfill formed between the portion of the conductive bumps and the corresponding conductive elements, the content of the conductive particles is greater than the content of the insulating particles.

After filling the underfill between the first electronic element and the second electronic element, the method can further comprise baking the semiconductor package at a temperature of 100 to 200° C. As such, the potential difference between the conductive bumps and the corresponding conductive elements is changed to cause the conductive particles in the underfill to move toward the gap between the portion of the conductive bumps and the corresponding conductive elements, thereby increasing the content of the conductive particles in the underfill between the portion of the conductive bumps and the corresponding conductive elements.

In the above-described package and method, the particle size of the conductive particles can be smaller than the particle size of the insulating particles.

In the above-described package and method, the conductive particles can be between 5 and 20 weight percent of the underfill.

In the above-described package and method, the insulating particles can be between 45 and 60 weight percent of the underfill.

In the above-described package and method, the polymer can be between 35 and 50 weight percent of the underfill.

In the above-described package and method, the conductive bumps can be made of copper, and the conductive elements can be made of Sn/Pb alloy.

In the above-described package and method, the first electronic element can be a substrate, a semiconductor chip, a wafer, or a packaged or unpackaged semiconductor element.

In the above-described package and method, the second electronic element can be a substrate, a semiconductor chip, a wafer, or a packaged or unpackaged semiconductor element.

Therefore, the present invention provides the underfill with the conductive particles having a particle size smaller than that of the insulating particles. As such, when a poor mechanical bonding occurs between the conductive bumps and the corresponding conductive elements, the present invention can electrically connect the conductive bumps and the corresponding conductive elements through the conductive particles.

Further, by baking the semiconductor package having the underfill, a potential difference is generated between the conductive particles, the conductive bumps and the conductive elements so as to cause the conductive particles to move toward and accumulate in the gap between the conductive bumps and the corresponding conductive elements, thus reducing the resistance of the conductive particles of the underfill between the conductive bumps and the corresponding conductive elements and improving the conductive performance.

### BRIEF DESCRIPTION OF DRAWINGS

FIG. 1 is a schematic cross-sectional view of a conventional semiconductor package;

FIG. 1′ is schematic cross-sectional view of a composite particle of a conventional anisotropic conductive film;

FIGS. 2A to 2C are schematic cross-sectional views showing a method for fabricating a semiconductor package according to the present invention; and

FIGS. 3A and 3B are partially enlarged cross-sectional views showing the steps of FIGS. 2B and 2C of the method of the present invention.

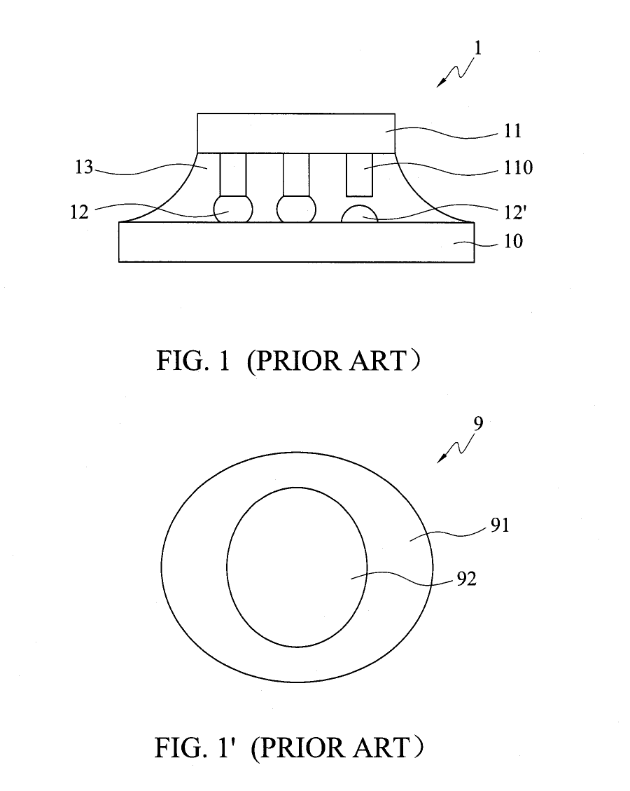

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention. Furthermore, the ranges of values written in the form “between . . . and . . . ” include the upper and lower limit values. For example, the phrase “between 0.1 and 1 um” is intended to include 0.1 um and 1 um.

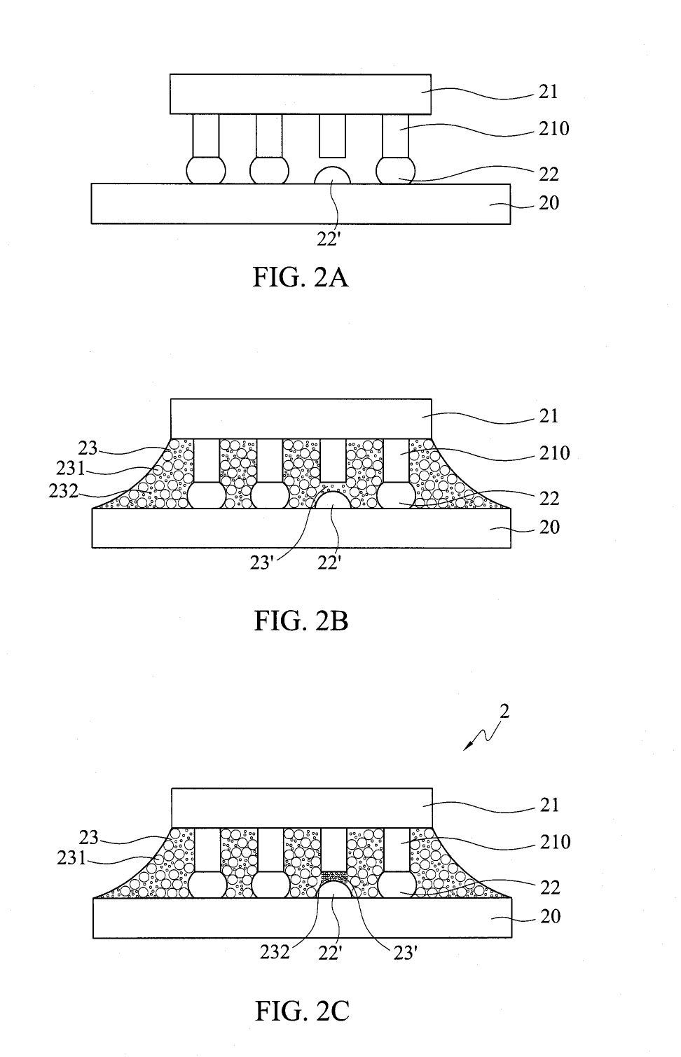

FIGS. 2A to 2C are schematic cross-sectional views showing a method for fabricating a semiconductor package according to the present invention.

Referring to FIG. 2A, a first electronic element 20 having a plurality of conductive elements 22 thereon is provided and a second electronic element 21 is disposed on the conductive elements 22 of the first electronic element 20 through a plurality of conductive bumps 210.

In the present embodiment, the second electronic element 21 can be, but not limited to, a substrate, a semiconductor chip, a wafer, or a packaged or unpackaged semiconductor element. The first electronic element 20 can be, but not limited to, a substrate, a semiconductor chip, a wafer, or a packaged or unpackaged semiconductor element. The conductive bumps 210 can be made of copper and the conductive elements 22 can be made of Sn/Pb alloy.

In an embodiment, a portion of the conductive elements 22′ are not mechanically connected to the corresponding conductive bumps 210.

Referring to FIG. 2B, an underfill 23 is filled between the second electronic element 21 and the first electronic element 20 for encapsulating the conductive bumps 210 and the conductive elements 22. The underfill 23 contains: a plurality of conductive particles 232 having a particle size between 0.1 and 1 um, a plurality of insulating particles 231 having a particle size between 1 and 10 um, and a polymer.

In the present embodiment, the particle size of the conductive particles is smaller than the particle size of the insulating particles. The conductive particles are between 5 and 20 weight percent of the underfill, the insulating particles are between 45 and 60 weight percent of the underfill, and the polymer is between 35 and 50 weight percent of the underfill. The conductive particles can be made of any conductive material.

In the present embodiment, since non-wetting occurs between a portion of the conductive bumps 210 and the corresponding conductive elements 22′, the underfill 23′ is further filled between the portion of the conductive bumps 210 and the corresponding conductive elements 22′.

Referring to FIG. 2C, the underfill 23, 23′ is cured by baking at a temperature of 100 to 200° C., thereby obtaining a semiconductor package 2.

After the baking process, in the underfill 23′ between the portion of the conductive bumps 210 and the corresponding conductive elements 22′, the content of the conductive particles 232 is greater than the content of the insulating particles 231.

Referring to FIG. 2C, the semiconductor package 2 of the present invention has: a first electronic element 20; a plurality of conductive elements 22 formed on the first electronic element 20; a second electronic element 21 having a plurality of conductive bumps 210 and disposed on the first electronic element 20 through the conductive bumps 210, wherein the conductive bumps 210 are correspondingly electrically connected to the conductive elements 22; and an underfill 23 formed between the second electronic element 21 and the first electronic element 20 for encapsulating the conductive bumps 210 and the conductive elements 22. The underfill 23 contains: a plurality of conductive particles 232 having a particle size between 0.1 and 1 um; a plurality of insulating particles 231 having a particle size between 1 and 10 um; and a polymer.

In an embodiment, the particle size of the conductive particles is smaller than the particle size of the insulating particles. The conductive particles are between 5 and 20 weight percent of the underfill, the insulating particles are between 45 and 60 weight percent of the underfill, and the polymer is between 35 and 50 weight percent of the underfill. The polymer can be an adhesive material. In the present embodiment, the polymer is an epoxy resin.

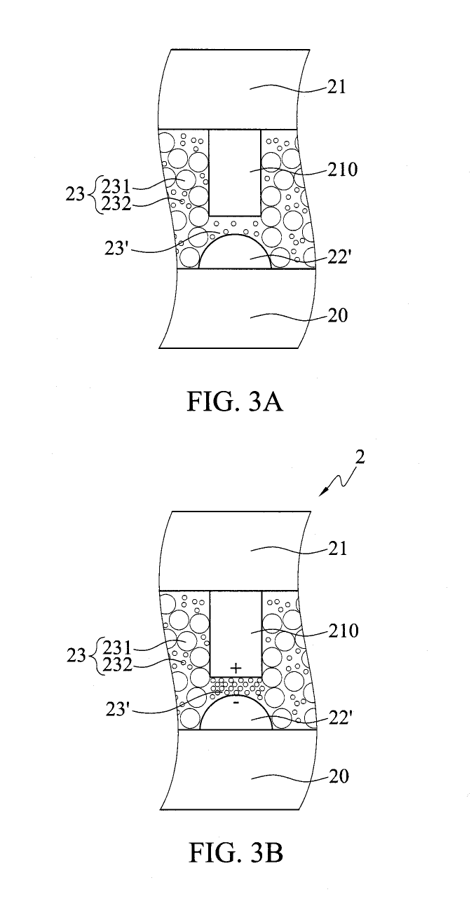

FIGS. 3A and 3B are partially enlarged cross-sectional views showing the steps of FIGS. 2B and 2C of the method of the present invention.

Referring to FIG. 3A, the underfill 23′ is formed between the portion of the conductive bumps 210 and the corresponding conductive elements 22′, and the underfill 23′ contains conductive particles 232.

In the present embodiment, since the conductive particles 232 have a small particle size, they can flow into the gap between the portion of the conductive bumps 210 and the corresponding conductive elements 22′ during dispensing of the underfill, thereby electrically connecting the portion of the conductive bumps 210 and the corresponding conductive elements 22′ and overcoming the non-wetting problem. Further, since the insulating particles 231 have a large particle size, they cannot easily move into the gap between the portion of the conductive bumps 210 and the corresponding conductive elements 22′. Therefore, different from the conductive particles 232 and the insulating particles 231 in the underfill 23 that are uniformly distributed, the content of the conductive particles 232 is greater than the content of the insulating particles 231 in the underfill 23′ between the conductive bumps 210 and the corresponding conductive elements 22′.

Referring to FIG. 3B, after the semiconductor package 2 is baked at a temperature of 100 to 200° C., the content of the conductive particles 232 is greater than the content of the insulating particles 231 in the underfill 23′ between the conductive bumps 210 and the corresponding conductive elements 22′.

In the present embodiment, after the baking process, a potential difference is generated between metal materials such as the conductive bumps, the conductive elements and the conductive particles to form positive and negative polarities, as shown in FIG. 3B.

For example, in the present embodiment, the conductive bumps are made of copper and heated to have a positive potential (+0.34V), and the conductive elements are made of Sn/Pb alloy and heated to have a negative potential (−0.138V). The potential difference between the conductive bumps and the conductive elements creates a local electric field effect that causes the conductive particles to move toward the gap between the conductive bumps and the conductive elements, thereby increasing the content of the conductive particles in the gap between the conductive bumps and the conductive elements.

Furthermore, before the baking process, the number of the conductive particles in the gap is quite small. Although the conductive bumps and the conductive elements can be electrically connected through the conductive particles, a high resistance is generated due to a small contact area, which prevents the flow of large current. After the baking process, the generated local electric field causes the conductive particles around a periphery of the gap to move toward the gap and accumulate in the gap, thereby improving the conductive performance between the conductive particles and the conductive elements and reducing the resistance. As such, the present invention overcomes the non-wetting problem.

According to the present invention, the conductive particles and the insulating particles of the underfill have certain particle size ranges and the conductive particles can be accumulated under an electric field generated by a potential difference between metals. As such, if a non-wetting problem occurs between the conductive bumps and the corresponding conductive elements, the conductive bumps and the corresponding conductive elements can still be electrically connected through the conductive particles. Further, the present invention only needs a general reflow process. Therefore, the present invention overcomes the non-wetting problem without the need of the conventional expensive and complicated flip-chip bonding using an ACF and effectively prevents bridging and cracking of the conductive bumps.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a first electronic element;
a plurality of conductive elements formed on the first electronic element;
a second electronic element having a plurality of conductive bumps and disposed on the first electronic element through the conductive bumps, wherein the conductive bumps are correspondingly electrically connected to the conductive elements; and
an underfill formed between the second electronic element and the first electronic element for encapsulating the conductive bumps and the conductive elements, wherein the underfill comprises:
a plurality of conductive particles having a particle size between 0.1 and 1 um;
a plurality of insulating particles having a particle size between 1 and 10 um; and
a polymer.

2. The package of claim 1, wherein the particle size of the conductive particles is smaller than the particle size of the insulating particles.

3. The package of claim 1, wherein the conductive particles are between 5 and 20 weight percent of the underfill.

4. The package of claim 1, wherein the insulating particles are between 45 and 60 weight percent of the underfill.

5. The package of claim 1, wherein the polymer is between 35 and 50 weight percent of the underfill.

6. The package of claim 1, wherein if a portion of the conductive bumps are not electrically connected to the corresponding conductive elements, in the underfill filled between the portion of the conductive bumps and the corresponding conductive elements, the content of the conductive particles is greater than the content of the insulating particles.

7. The package of claim 1, wherein the conductive bumps are made of copper.

8. The package of claim 1, wherein the conductive elements are made of Sn/Pb alloy.

9. The package of claim 1, wherein the first electronic element is a substrate, a semiconductor chip, a wafer, or a packaged or unpackaged semiconductor element.

10. The package of claim 1, wherein the second electronic element is a substrate, a semiconductor chip, a wafer, or a packaged or unpackaged semiconductor element.

11. A method for fabricating a semiconductor package, comprising the steps of:
providing a first electronic element having a plurality of conductive elements thereon and disposing a second electronic element on the conductive elements of the first electronic element through a plurality of conductive bumps; and
filling an underfill between the second electronic element and the first electronic element for encapsulating the conductive bumps and the conductive elements, wherein the underfill comprises:
a plurality of conductive particles having a particle size between 0.1 and 1 um;
a plurality of insulating particles having a particle size between 1 and 10 um; and
a polymer.

12. The method of claim 11, wherein the particle size of the conductive particles is smaller than the particle size of the insulating particles.

13. The method of claim 11, wherein the conductive particles are between 5 and 20 weight percent of the underfill.

14. The method of claim 11, wherein the insulating particles are between 45 and 60 weight percent of the underfill.

15. The method of claim 11, wherein the polymer is between 35 and 50 weight percent of the underfill.

16. The method of claim 11, wherein the underfill is further filled between a portion of the conductive bumps and the corresponding conductive elements, and in the underfill formed between the portion of the conductive bumps and the corresponding conductive elements, the content of the conductive particles is greater than the content of the insulating particles.

17. The method of claim 16, after filling the underfill between the first electronic element and the second electronic element, further comprising baking the semiconductor package at a temperature of 100 to 200° C.

18. The method of claim 11, wherein the conductive bumps are made of copper.

19. The method of claim 11, wherein the conductive elements are made of Sn/Pb alloy.

20. The method of claim 11, wherein the first electronic element is a substrate, a semiconductor chip, a wafer, or a packaged or unpackaged semiconductor element.

21. The method of claim 11, wherein the second electronic element is a substrate, a semiconductor chip, a wafer, or a packaged or unpackaged semiconductor element.
